(19) United States
(12) Patent Application Publication
(10) Pub. No.: US 2025/0346152 A1
(43) Pub. Date: Nov. 13, 2025

(54) VEHICLE CONTROL APPARATUS AND METHOD

(71) Applicants: HYUNDAI MOTOR COMPANY, Seoul (KR); KIA CORPORATION, Seoul (KR)

(72) Inventors: Yo Han Baek, Hwaseong-si (KR); Yoon Sung Choi, Hwaseong-si (KR)

(73) Assignees: HYUNDAI MOTOR COMPANY, Seoul (KR); KIA CORPORATION, Seoul (KR)

(21) Appl. No.: 18/930,553

(22) Filed: Oct. 29, 2024

(30) Foreign Application Priority Data
May 8, 2024 (KR) 10-2024-0060624

(51) Int. Cl. B60L 58/18; B60L 58/12; G01R 31/00; G01R 31/382; G01R 31/396; H01M 10/42; H01M 10/48

(52) U.S. Cl. CPC B60L 58/18; B60L 58/12; G01R 31/006; G01R 31/382; G01R 31/396; H01M 10/425; H01M 10/482; H01M 2010/4271; H01M 2220/20

(57) ABSTRACT

A vehicle control apparatus and a vehicle control method are provided. The vehicle control apparatus includes a first battery pack, a second battery pack, and a processor. The processor determines a risk level of at least one of the first battery pack or the second battery pack based on a difference between a first pack voltage and a second pack voltage. The processor measures at least one of a first state of charge (SOC) of the first battery pack, a second SOC of the second battery pack, or any combination thereof, based on that the risk level is determined. The processor determines whether the at least one of the first battery pack, the second battery pack, or the any combination thereof is abnormal, based on at least one of a first variance in the first Soc, a second variance in the second SOC, or any combination thereof.

### CROSS-REFERENCE TO RELATED APPLICATION

This application claims the benefit of and priority to Korean Patent Application No. 10-2024-0060624, filed in the Korean Intellectual Property Office on May 8, 2024, the entire contents of which are incorporated herein by reference.

### TECHNICAL FIELD

The present disclosure relates to a vehicle control apparatus and method, and more particularly, relates to technologies for determining whether a battery packet is abnormal.

### BACKGROUND

With the development of technology for an eco-friendly vehicle, continuous research for a battery loaded into the eco-friendly vehicle has been in progress. For example, the eco-friendly vehicle may include a hybrid electric vehicle (HEV), an electric vehicle (EV), a plug-in hybrid electric vehicle (PHEV), and/or a fuel cell electric vehicle (FCEV).

Various studies for diagnosing whether a battery pack included in the eco-friendly vehicle is abnormal are in progress. There is a need to accurately determine whether a battery pack is abnormal.

The statements in this Background section merely provide background information related to the present disclosure and may not constitute prior art.

### SUMMARY

The present disclosure has been made to solve the above-mentioned problems occurring in the prior art while advantages achieved by the prior art are maintained intact.

An aspect of the present disclosure provides a vehicle control apparatus for overcoming a limitation due to low voltage sensing resolution in a commercial EV which uses a plurality of battery system assemblies (BSAs) and a method thereof.

Another aspect of the present disclosure provides a vehicle control apparatus and method for determining whether there is an external resistor of a cell electrode using a plurality of voltage and current sensors loaded into the plurality of BSAs.

Another aspect of the present disclosure provides a vehicle control apparatus and method for detecting whether abnormality occurs in a battery pack and preventing fire.

The technical problems to be solved by the present disclosure are not limited to the aforementioned problems, and any other technical problems not mentioned herein should be clearly understood from the following description by those having ordinary skill in the art to which the present disclosure pertains.

According to an aspect of the present disclosure, a vehicle control apparatus may include a first battery pack, a second battery pack, and a processor. The processor may determine a risk level of at least one of the first battery pack, the second battery pack, or any combination thereof, based on a difference between a first pack voltage of the first battery pack and a second pack voltage of the second battery pack. The processor may also measure at least one of a first state of charge (SOC) of the first battery pack, a second SOC of the second battery, or any combination thereof, based on that the risk level of the at least one of the first battery pack, the second battery pack, or the any combination thereof is determined. The processor may further determine whether the at least one of the first battery pack, the second battery pack, or the any combination thereof is abnormal, based on at least one of a first variance in the first SOC, a second variance in the second SOC, or any combination thereof.

In an embodiment, the processor may identify the first pack voltage and the second pack voltage, based on identifying a first internal current of the first battery pack and a second internal current of the second battery pack.

In an embodiment, the first battery pack may include a plurality of first battery cells, and the second battery pack may include a plurality of second battery cells. In an embodiment, the processor may determine the risk level of the first battery pack, based on that the sum of voltages of the plurality of first battery cells and the first pack voltage are different from each other or may determine the risk level of the second battery pack, based on that the sum of voltages of the plurality of second battery cells and the second pack voltage are different from each other

In an embodiment, the processor may measure the at least one of the first soc, the second SOC, or the any combination thereof, based on that a state of a vehicle including the first battery pack and the second battery pack changes from an ignition (Ig)-on state to a state different from the Ig-on state. The processor may also measure the at least one of the first variance, the second variance, or the any combination thereof, based on that the state of the vehicle changes from a state different from the Ig-on state to the Ig-on state.

In an embodiment, the processor may determine an abnormal state of the first battery pack when the first variance is greater than the second variance or may determine an abnormal state of the second battery pack when the second variance is greater than the first variance.

In an embodiment, the processor may obtain the first pack voltage, based on a voltage of the first battery pack measured during a specified time or may obtain the second pack voltage, based on a voltage of the second battery pack measured during the specified time.

In an embodiment, the processor may determine that the risk level of the at least one of the first battery pack, the second battery pack, or the any combination thereof is a first level, based on that a difference between the first pack voltage and the second pack voltage is greater than or equal to a first threshold and is less than a second threshold.

In an embodiment, the processor may determine that the risk level of the at least one of the first battery pack, the second battery pack, or the any combination thereof is a second level indicating greater risk than the first level, based on that the difference between the first pack voltage and the second pack voltage is greater than or equal to the second threshold.

In an embodiment, the processor may identify at least one of a first internal current of the first battery pack, a second internal current of the second battery pack, or any combination thereof. The processor may further determine whether the at least one of the first internal current, the second internal current, or the any combination thereof is in a first interval less than or equal to a first reference value, in a second interval greater than the first reference value and less than or equal to a second reference value, or in a third interval greater than the second reference value. The processor may further determine the risk level of the at least one of the first battery pack, the second battery pack, or the any combination thereof, based on an interval in which there is the at least one of the first internal current, the second internal current, or the any combination thereof.

In an embodiment, the processor may identify a first number of times that the risk level of the at least one of the first battery pack, the second battery pack, or the any combination thereof is determined. The processor may further identify a second number of times that an abnormal state of the at least one of the first battery pack, the second battery pack, or the any combination thereof is determined. The processor may also determine that there is an element causing an increase in a resistance value in an inside of the at least one of the first battery pack, the second battery pack, or the any combination thereof, based on that the first number of times is greater than or equal to a specified number of times and the second number of times is greater than or equal to the specified number of times.

In an embodiment, the processor may identify a first number of times that the risk level of the at least one of the first battery pack, the second battery pack, or the any combination thereof is determined. The processor may further identify a second number of times that an abnormal state of the at least one of the first battery pack, the second battery pack, or the any combination thereof is determined. The processor may also store at least one of the first number of times, the second number of times, or any combination thereof, based on that at least one of the first number of times, the second number of times, or any combination thereof is less than a specified number of times.

In an embodiment, the processor may output whether the at least one of the first battery pack, the second battery pack, or the any combination thereof is abnormal.

According to an aspect of the present disclosure, a vehicle control method may include: determining, by a processor, a risk level of at least one of a first battery pack, a second battery pack, or any combination thereof, based on a difference between a first pack voltage of the first battery pack and a second pack voltage of the second battery pack; measuring, by the processor, at least one of a first state of charge (SOC) of the first battery pack, a second SOC of the second battery, or any combination thereof, based on that the risk level of the at least one of the first battery pack, the second battery pack, or the any combination thereof is determined; determining, by the processor, whether the at least one of the first battery pack, the second battery pack, or the any combination thereof is abnormal, based on at least one of a first variance in the first Soc, a second variance in the second SOC, or any combination thereof; and outputting, by the processor, whether the at least one of the first battery pack, the second battery pack, or the any combination thereof is abnormal.

The vehicle control method according to an embodiment may further include identifying the first pack voltage and the second pack voltage, based on identifying a first internal current of the first battery pack and a second internal current of the second battery pack.

In an embodiment, the first battery pack may include a plurality of first battery cells, and the second battery pack may include a plurality of second battery cells. The vehicle control method may further include determining the risk level of the first battery pack, based on that the sum of voltages of the plurality of first battery cells and the first pack voltage are different from each other, or determining the risk level of the second battery pack, based on that the sum of voltages of the plurality of second battery cells and the second pack voltage are different from each other.

The vehicle control method according to an embodiment may further include: measuring the at least one of the first SOC, the second SOC, or the any combination thereof, based on that a state of a vehicle including the first battery pack and the second battery pack changes from an ignition (Ig)-on state to a state different from the Ig-on state; and measuring the at least one of the first variance, the second variance, or the any combination thereof, based on that a state of the vehicle changes from the state different from the Ig-on state to the Ig-on state.

The vehicle control method according to an embodiment may further include: determining an abnormal state of the first battery pack when the first variance is greater than the second variance; or determining an abnormal state of the second battery pack when the second variance is greater than the first variance.

The vehicle control method according to an embodiment may further include: obtaining the first pack voltage, based on a voltage of the first battery pack measured during a specified time; or obtaining the second pack voltage, based on a voltage of the second battery pack measured during the specified time.

The vehicle control method according to an embodiment may further include: determining that the risk level of the at least one of the first battery pack, the second battery, or the any combination thereof is a first level, based on that a difference between the first pack voltage and the second pack voltage is greater than or equal to a first threshold and is less than a second threshold; or determining that the risk level of the at least one of the first battery pack, the second battery pack, the any combination thereof is a second level indicating greater risk than the first level, based on that the difference between the first pack voltage and the second pack voltage is greater than or equal to the second threshold.

The vehicle control method according to an embodiment may further include: identifying at least one of a first internal current of the first battery pack, a second internal current of the second battery pack, or any combination thereof; determining whether the at least one of the first internal current, the second internal current, or the any combination thereof is in a first interval less than or equal to a first reference value, in a second interval greater than the first reference value and less than or equal to a second reference value, or in a third interval greater than the second reference value; and determining the risk level of the at least one of the first battery pack, the second battery pack, or the any combination thereof, based on an interval in which there is the at least one of the first internal current, the second internal current, or the any combination thereof.

The vehicle control method according to an embodiment may further include: identifying a first number of times that the risk level of the at least one of the first battery pack, the second battery pack, or the any combination thereof is determined; identifying a second number of times that an abnormal state of the at least one of the first battery pack, the second battery pack, or the any combination thereof is determined; and determining that there is an element causing an increase in a resistance value in an inside of the at least one of the first battery pack, the second battery pack, or the any combination thereof, based on that the first number of times is greater than or equal to a specified number of times and the second number of times is greater than or equal to the specified number of times.

### BRIEF DESCRIPTION OF THE DRAWINGS

The above and other objects, features and advantages of the present disclosure should be more apparent from the following detailed description taken in conjunction with the accompanying drawings:

FIG. 1 illustrates an example of a block diagram associated with a vehicle control apparatus according to an embodiment of the present disclosure;

FIG. 2 illustrates an example of battery packs included in a vehicle, in an embodiment of the present disclosure;

FIG. 3 illustrates an example of a flowchart associated with a vehicle control method according to an embodiment of the present disclosure;

FIGS. 4A and 4B illustrate an example of a flowchart associated with a vehicle control method according to an embodiment of the present disclosure;

FIGS. 5A and 5B illustrate an example of a flowchart associated with a vehicle control method according to an embodiment of the present disclosure;

FIG. 6 illustrates an example of a flowchart associated with a vehicle control method according to an embodiment of the present disclosure;

FIG. 7 illustrates an example of a flowchart associated with a vehicle control method according to an embodiment of the present disclosure; and

FIG. 8 illustrates a computing system associated with a vehicle control apparatus or a vehicle control method according to an embodiment of the present disclosure.

The drawings described herein are for illustration purposes only and are not intended to limit the scope of the present disclosure in any way.

### DETAILED DESCRIPTION

Hereinafter, some embodiments of the present disclosure are described in detail with reference to the drawings. In adding the reference numerals to the components of each drawing, it should be noted that the identical component is designated by the identical numerals even when they are displayed on other drawings. In addition, a detailed description of well-known features or functions has been ruled out in order not to unnecessarily obscure the gist of the present disclosure.

In describing components of embodiments of the present disclosure, the terms first, second, A, B, (a), (b), and the like may be used herein. These terms are only used to distinguish one component from another component, but do not limit the corresponding components irrespective of the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

When a component, controller, processor, unit, module, hardware, device, element, apparatus, or the like of the present disclosure is described as having a purpose or performing an operation, function, or the like, the component, controller, processor, unit, module, hardware, device, element, apparatus, or the like should be considered herein as being “configured to” meet that purpose or to perform that operation or function.

In the present disclosure, each of phrases such as “A or B,” “at least one of A and B,” “at least one of A or B,” “A, B or C,” “at least one of A, B and C,” “at least one of A, B or C,” and “at least one of A, B, or C, or a combination thereof” may include any one or all possible combinations of the items listed together in the corresponding one of the phrases.

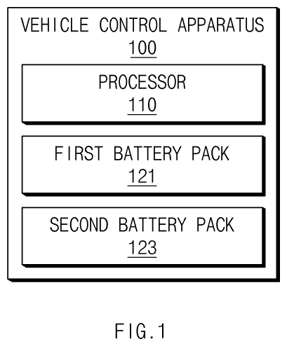

Hereinafter, embodiments of the present disclosure are described in detail with reference to FIGS. 1 to 8.

FIG. 1 illustrates an example of a block diagram associated with a vehicle control apparatus according to an embodiment of the present disclosure.

Referring to FIG. 1, a vehicle control apparatus 100 according to an embodiment of the present disclosure may be implemented inside or outside a vehicle, and some of the components included in the vehicle control apparatus 100 may be implemented inside or outside the vehicle. In this case, the vehicle control apparatus 100 may be integrally configured with control units in the vehicle or may be implemented as a separate device to be connected with the control units of the vehicle by a separate connection means. For example, the vehicle control apparatus 100 may further include components which are not shown in FIG. 1.

According to an embodiment, the vehicle control apparatus 100 may include a processor 110, a first battery pack 121, and a second battery pack 123. The processor 110, the first battery pack 121, and the second battery pack 123 may be electronically or operably coupled with each other by an electronical component including a communication bus.

Hereinafter, that pieces of hardware are operably coupled with each other may include that a direct connection or an indirect connection between the pieces of hardware is established in a wired or wireless manner, such that second hardware is controlled by first hardware.

The different blocks are illustrated, but an embodiment is not limited thereto. For example, some of the pieces of hardware of FIG. 1 may be included in a single integrated circuit including a system on a chip (SoC). Types of the pieces of hardware included in the vehicle control apparatus 100 and/or the number of the pieces of hardware are/is not limited to those shown in FIG. 1. For example, the vehicle control apparatus 100 may include only some of the pieces of hardware shown in FIG. 1.

The vehicle control apparatus 100 according to an embodiment may include hardware for processing data based on one or more instructions. The hardware for processing the data may include the processor 110.

For example, the hardware for processing the data may include an arithmetic and logic unit (ALU), a floating point unit (FPU), a field programmable gate array (FPGA), a central processing unit (CPU), and/or an application processor (AP). The processor 110 may have a structure of a single-core processor or may have a structure of a multi-core processor including a dual core, a quad core, a hexa core, or an octa core.

The first battery pack 121 of the vehicle control apparatus 100 may include at least one of a relay, a control unit, a sensor, or a battery cell, or any combination thereof.

For example, the first battery pack 121 may include a plurality of first battery cells. For example, the control unit included in the first battery pack 121 may include at least one of a battery management unit (BMU) or a cell monitoring unit (CMU), or any combination thereof. For example, the first battery pack 121 may include at least one of a battery cell, a module, or a sub-module, or any combination thereof. For example, the second battery pack 123 may be substantially the same as the first battery pack 121. For example, the second battery pack 123 may include a plurality of second battery cells.

The processor 110 of the vehicle control apparatus 100 according to embodiment may identify a first pack voltage of the first battery pack 121 and a second pack voltage of the second battery pack 123. For example, the processor 110 may determine a risk level of at least one of the first battery pack 121 or the second battery pack 123, or any combination thereof, based on a difference between the first pack voltage of the first battery pack 121 and the second pack voltage of the second battery pack 123.

For example, the processor 110 may identify the sum of voltages of the plurality of first battery cells included in the first battery pack 121. The processor 110 may identify the first pack voltage, based on the sum of the voltages of the plurality of first battery cells.

For example, the processor 110 may identify the sum of voltages of the plurality of second battery cells included in the second battery pack 123. The processor 110 may identify the second pack voltage, based on the sum of the voltages of the plurality of second battery cells.

For example, the processor 110 may obtain the first pack voltage, based on a voltage of the first battery pack 121, which is measured during a specified time. For example, the processor 110 may obtain the second pack voltage, based on a voltage of the second battery pack 123, which is measured during the specified time. For example, the specified time may include about 2 seconds. However, an embodiment of the present disclosure is not limited to that described above.

For example, the processor 110 may identify a first internal current of the first battery pack 121. For example, the processor 110 may identify a second internal current of the second battery pack 123. For example, the processor 110 may identify the first pack voltage and the second pack voltage, based on identifying the first internal current of the first battery pack 121 and the second internal current of the second battery pack 123.

For example, the processor 110 may identify that the difference between the first pack voltage and the second pack voltage is greater than or equal to a first threshold and is less than a second threshold. For example, the processor 110 may determine that the risk level of the at least one of the first battery pack 121 or the second battery pack 123, or the any combination thereof is a first level, based on that the difference between the first pack voltage and the second pack voltage is greater than or equal to the first threshold and is less than the second threshold. For example, the first threshold may include about 1 volt (V). For example, the second threshold may include about 2 V.

For example, the processor 110 may determine that the risk level of the at least one of the first battery pack 121 or the second battery pack 123, or the any combination thereof is a second level indicating greater risk than the first level, based on that the difference between the first pack voltage and the second pack voltage is greater than or equal to the second threshold.

In an embodiment, the processor 110 may identify at least one of the first internal current of the first battery pack 121 or the second internal current of the second battery pack 123, or any combination thereof.

For example, the processor 110 may identify whether the at least one of the first internal current or the second internal current or the any combination thereof is greater than a first reference value. For example, the processor 110 may identify whether the at least one of the first internal current or the second internal current or the any combination thereof is less than or equal to the first reference value. For example, the processor 110 may identify whether the at least one of the first internal current or the second internal current or the any combination thereof is greater than a second reference value greater than the first reference value. For example, the processor 110 may identify whether the at least one of the first internal current or the second internal current or the any combination thereof is greater than the first reference value and is less than or equal to the second reference value. For example, the first reference value may include about 1 V/20 mohm. For example, the second reference value may include about 2 V/20 mohm. For example, the processor 110 may determine the risk level of the at least one of the first battery pack 121 or the second battery pack 123, or the any combination thereof, based on an interval including the at least one of the first internal current or the second internal current, or the any combination thereof.

In an embodiment, the processor 110 may identify the risk level of the at least one of the first battery pack 121 or the second battery pack 123, or any combination thereof. The processor 110 may measure at least one of a first state of charge (SOC) of the first battery pack 121 or a second SOC of the second battery pack 123, or any combination thereof, based on that the risk level of the at least one of the first battery pack 121 or the second battery pack 123, or the any combination thereof is identified.

For example, the processor 110 may identify that the sum of the voltages of the plurality of first battery cells included in the first battery pack 121 and the first pack voltage are different from each other. The processor 110 may identify the risk level of the first battery pack 121, based on that the sum of the voltages of the plurality of first battery cells and the first pack voltage are different from each other.

For example, the processor 110 may identify that the sum of the voltages of the plurality of second battery cells included in the second battery pack 123 and the second pack voltage are different from each other. The processor 110 may identify the risk level of the second battery pack 123, based on that the sum of the voltages of the plurality of second battery cells and the second pack voltage are different from each other.

In an embodiment, the processor 110 may identify at least one of a first variance in the first SOC or a second variance in the second SOC, or any combination thereof. For example, the processor 110 may identify the at least one of the first variance in the first SOC or the second variance in the second SOC, or the any combination thereof, based on a change in state of a vehicle including the first battery pack 121 and the second battery pack 123.

For example, the processor 110 may determine whether the at least one of the first battery pack 121 or the second battery pack 123, or the any combination thereof is abnormal, based on the at least one of the first variance in the first SOC or the second variance in the second SOC, or the any combination thereof. For example, the processor 110 may identify the first variance in the first Soc, based on a difference between the first SOC at a first time point and the first SOC at a second time point. For example, the processor 110 may identify the second variance in the second soc, based on a difference between the second SOC at the first time point and the second SOC at the second time point.

For example, the processor 110 may identify that the state of the vehicle including the first battery pack 121 and the second battery pack 123 changes from an ignition (Ig)-on state to a state different from the Ig-on state. The processor 110 may identify the at least one of the first SOC or the second SOC, or the any combination thereof, based on that the state of the vehicle including the first battery pack 121 and the second battery pack 123 changes from the Ig-on state to the state different from the Ig-on state.

For example, the processor 110 may identify that the state of the vehicle changes from the state different from the Ig-on state to the Ig-on state. The processor 110 may identify the at least one of the first variance in the first SOC or the second variance in the second SOC, or the any combination thereof, based on that the state of the vehicle changes from the state different from the Ig-on state to the Ig-on state.

For example, the processor 110 may identify the at least one of the first Soc or the second SOC, or the any combination thereof, at the first time point when the state of the vehicle changes from the Ig-on state to the state different from the Ig-on state. The processor 110 may identify the at least one of the first SOC or the second SOC, or the any combination thereof, at the second time point when the state the vehicle changes from the state different from the Ig-on state to the Ig-on state. The processor 110 may identify the at least one of the first variance in the first SOC or the second variance in the second SOC, or the any combination thereof, based on a difference between the at least one of the first SOC or the second SOC, or the any combination thereof, which is identified at the first time point, and the at least one of the first SOC or the second SOC, or the any combination thereof, which is identified at the second time point.

For example, if the first variance between the first variance and the second variance is greater than the second variance, the processor 110 may determine an abnormal state of the first battery pack 121. For example, if the second variance between the first variance and the second variance is greater than the first variance, the processor 110 may determine an abnormal state of the second battery pack 123.

In an embodiment, the processor 110 may output whether the at least one of the first battery pack 121 or the second battery pack 123, or the any combination thereof is abnormal. For example, the processor 110 may output whether the at least one of the first battery pack 121 or the second battery pack 123, or the any combination thereof is abnormal, based on determining whether the at least one of the first battery pack 121 or the second battery pack 123, or the any combination thereof is abnormal.

In an embodiment, the processor 110 may identify that the risk level of the at least one of the first battery pack 121 or the second battery pack 123, or any combination thereof is identified a specified number of times or more. The processor 110 may determine whether abnormality in the at least one of the first battery pack 121 or the second battery pack 123, or the any combination thereof is identified the specified number of times or more.

For example, the processor 110 may determine that there is an element causing an increase in resistance value in the inside of the at least one of the first battery pack 121 or the second battery pack 123, or the any combination thereof, based on that both the risk level and the abnormality are identified the specified number of times or more. For example, the element causing the increase in resistance value may include at least one of a serial resistor between battery cells, an inductor, a conductor, a busbar, or a bolt, or any combination thereof. However, an embodiment of the present disclosure is not limited to that described above.

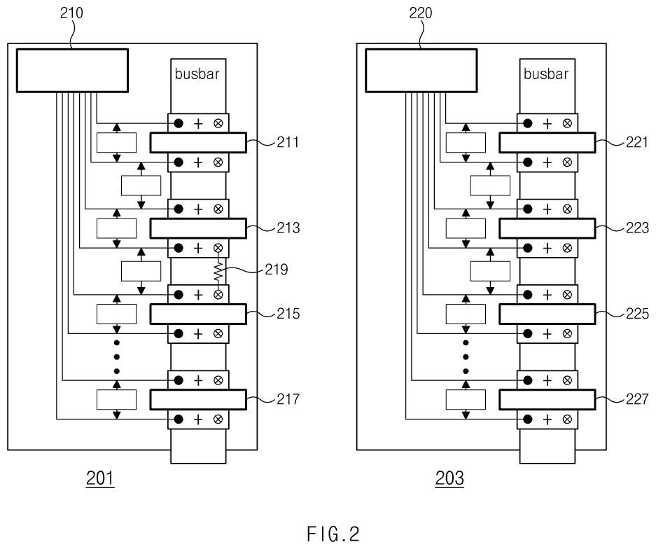

FIG. 2 illustrates an example of battery packs included in a vehicle, in an embodiment of the present disclosure.

Referring to FIG. 2, a processor (e.g., a processor 110 of FIG. 1) of a vehicle control apparatus (e.g., a vehicle control apparatus 100 of FIG. 1) according to an embodiment may identify a pack voltage of at least one of a first battery pack 201 or a second battery pack 203, or any combination thereof.

For example, the first battery pack 201 may include at least one of a control unit 210 or a plurality of first battery cells 211, 213, 215, and 217, or any combination thereof. For example, the first battery pack 201 may further include a serial resistor 219 connected between the first cell 213 and the second cell 215 among the plurality of first battery cells 211, 213, 215, and 217.

For example, if the serial resistor 219 is further included like the first battery pack 201, a first pack voltage of the first battery pack 201 may be different from the sum of voltages of the plurality of first battery cells 211, 213, 215, and 217. For example, because a voltage drop occurs in the serial resistor 219 included in the first battery pack 201, the first pack voltage may be different from the sum of the voltages of the plurality of first battery cells 211, 213, 215, and 217.

For example, the second battery pack 203 may include at least one of a control unit 220 or a plurality of second battery cells 221, 223, 225, and 227, or any combination thereof. For example, a second pack voltage of the second battery pack 203 may be the same as the sum of voltages of the plurality of second battery cells 221, 223, 225, and 227.

As described above, the processor of the vehicle control apparatus according to embodiment may determine whether the first battery pack 201 is abnormal, based on that the first pack voltage of the first battery pack 201 is different from the sum of the voltages of the plurality of first battery cells 211, 213, 215, and 217. The example including the serial resistor 219 which is connected between the cells included in the first battery pack 201 is described for convenience of description, but an embodiment of the present disclosure is not limited thereto.

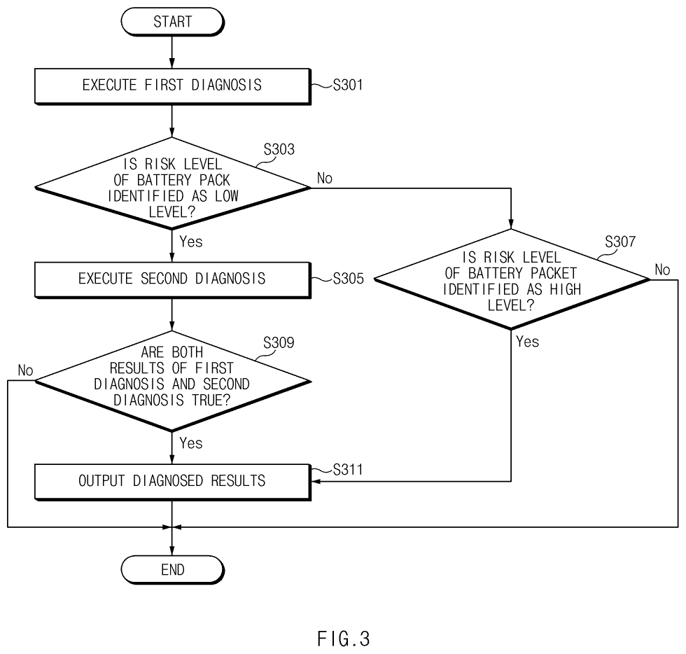

FIG. 3 illustrates an example of a flowchart associated with a vehicle control method according to an embodiment of the present disclosure.

Hereinafter, it is assumed that a vehicle control apparatus 100 of FIG. 1 performs a process of FIG. 3. Furthermore, in a description of FIG. 3, an operation described as being performed by an apparatus may be understood as being controlled by a processor 110 of the vehicle control apparatus 100.

At least one of the operations of FIG. 3 may be performed by the vehicle control apparatus 100 of FIG. 1. At least one of the operations of FIG. 3 may be controlled by the processor 110 of FIG. 1. The respective operations of FIG. 3 may be sequentially performed, but are not necessarily sequentially performed. For example, an order of the respective operations may be changed, and at least two operations may be performed in parallel.

Referring to FIG. 3, in an operation S301, the vehicle control method according to an embodiment may include executing a first diagnosis. For example, the first diagnosis may be performed in real time. For example, the vehicle control method may include executing the first diagnosis, if a vehicle is driving or the vehicle changes to an ignition (Ig)-on state.

In an operation S303, the vehicle control method according to an embodiment may include determining whether a risk level of a battery pack is identified as a low level. For example, the vehicle control method may include identifying the risk level of the battery pack, based on the pack voltage of the battery pack.

If the risk level of the battery pack is identified as the low level (Yes in the operation S303), in an operation S305, the vehicle control method according to an embodiment may include executing a second diagnosis. For example, the second diagnosis may be executed in trip units. For example, the trip units may include one cycle in which the state of the vehicle changes from an Ig-on state to a state different from the Ig-on state.

If the risk level of the battery pack is not identified as the low level (No in the operation S303), in an operation S307, the vehicle control method according to an embodiment may include determining whether the risk level of the battery pack is identified as a high level.

In an operation S309, the vehicle control method according to an embodiment may include identifying whether both the results of the first diagnosis and the second diagnosis are true.

For example, the case in which both the results of the first diagnosis and the second diagnosis are true may include a case in which the risk level of the battery pack is determined using the first diagnosis and it is determined whether the battery pack is abnormal using the second diagnosis.

If both the results of the first diagnosis and the second diagnosis are true (Yes in the operation S309) or if the risk level of the battery pack is identified as the high level (Yes in the operation S307), in an operation S311, the vehicle control method according to embodiment may include outputting the diagnosed results.

If at least one of the results of the first diagnosis and the second diagnosis is not true (No in the operation S309) or if the risk level of the battery pack is not identified as the high level (No in the operation S307), vehicle control method according to embodiment may include ending the process.

For example, if the at least one of the results of the first diagnosis and the second diagnosis is not true, the vehicle control method according to embodiment may include ending the process. For example, the case in which the result of the second diagnosis is not true may include a case in which it is not determined whether both the first battery pack and the second battery pack are abnormal.

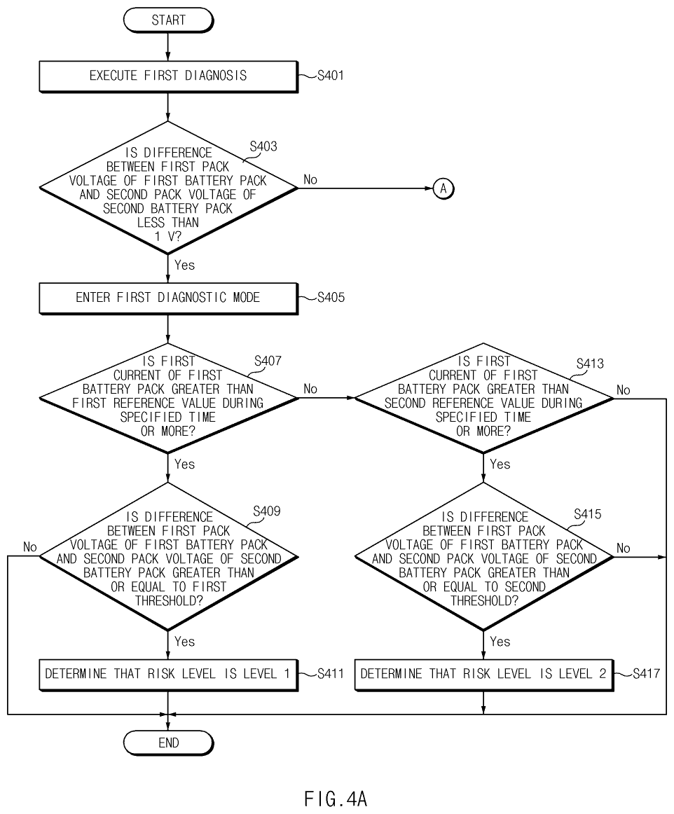

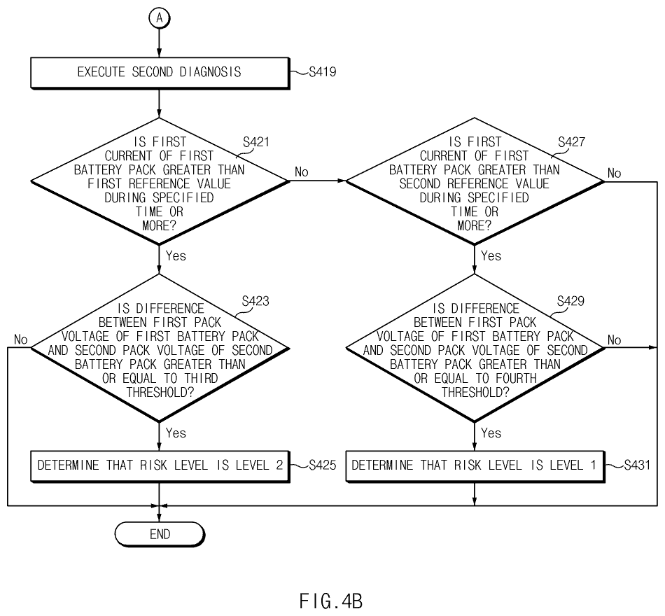

FIGS. 4A and 4B illustrate an example of a flowchart associated with a vehicle control method according to an embodiment of the present disclosure.

Hereinafter, it is assumed that a vehicle control apparatus 100 of FIG. 1 performs processes of FIGS. 4A and 4B. Furthermore, in descriptions of FIGS. 4A and 4B, an operation described as being performed by an apparatus may be understood as being controlled by a processor 110 of the vehicle control apparatus 100.

At least one of the operations of FIGS. 4A and 4B may be performed by the vehicle control apparatus 100 of FIG. 1. At least one of the operations of FIGS. 4A and 4B may be controlled by the processor 110 of FIG. 1. The respective operations of FIGS. 4A and 4B may be sequentially performed, but are not necessarily sequentially performed. For example, an order of the respective operations may be changed, and at least two operations may be performed in parallel.

Referring to FIGS. 4A and 4B, in an operation S401, the vehicle control method according to an embodiment may include executing a first diagnosis. FIGS. 4A and 4B may include details associated with the first diagnosis. For example, the vehicle control method may include performing the operations of FIGS. 4A and 4B, based on S301 of FIG. 3.

In an operation S403, the vehicle control method according to embodiment may include identifying whether a difference between a first pack voltage of a first battery pack and a second pack voltage of a second battery pack is less than 1 V.

If the difference between the first pack voltage of the first battery pack and the second pack voltage of the second battery pack is less than 1 V (Yes in the operation S403), in an operation S405, the vehicle control method according to embodiment may include entering a first diagnostic mode. For example, the first diagnostic mode may be referred to as a balanced packet diagnostic mode.

In an operation S407, the vehicle control method according to embodiment may include identifying whether a first current of the first battery pack is greater than a first reference value during a specified time or more.

For example, the first reference value may include about 1 V/20 mohm. For example, the specified time may include about 2 seconds.

If the first current of the first battery pack is greater than the first reference value during the specified time or more (Yes in the operation S407), in an operation S409, the vehicle control method according to embodiment may include identifying whether the difference between the first pack voltage of the first battery pack and the second pack voltage of the second battery pack is greater than or equal to a first threshold.

For example, the first threshold may include about 1 V.

If the difference between the first pack voltage of the first battery pack and the second pack voltage of the second battery pack is greater than or equal to the first threshold (Yes in the operation S409), in an operation S411, the vehicle control method according to embodiment may include determining that the risk level is level 1.

If the first current of the first battery pack is not greater than the first reference value during the specified time or more (No in the operation S407), in an operation S413, the vehicle control method according to embodiment may include identifying whether the first current of the first battery pack is greater than a second reference value during the specified time or more.

For example, the second reference value may include about 2 V/20 mohm.

If the first current of the first battery pack is greater than the second reference value during the specified time or more (Yes in the operation S413), in an operation S415, the vehicle control method according to embodiment may include identifying whether the difference between the first pack voltage of the first battery pack and the second pack voltage of the second battery pack is greater than or equal to a second threshold.

For example, the second threshold may include about 2 V. If the difference between the first pack voltage of the first battery pack and the second pack voltage of the second battery pack is greater than or equal to the second threshold (Yes in the operation S415), in an operation S417, the vehicle control method according to embodiment may include determining that the risk level is level 2.

If the difference between the first pack voltage of the first battery pack and the second pack voltage of the second battery pack is not less than 1 V (No in the operation S403), in an operation S419, the vehicle control method according to embodiment may include entering a second diagnostic mode.

For example, the second diagnostic mode may be referred to as an unbalanced packet diagnostic mode.

In an operation S421, the vehicle control method according to embodiment may include identifying whether the first current of the first battery pack is greater than the first reference value during the specified time or more.

If the first current of the first battery pack is greater than the first reference value during the specified time or more (Yes in the operation S421), in an operation S423, the vehicle control method according to embodiment may include identifying whether the difference between the first pack voltage of the first battery pack and the second pack voltage of the second battery pack is greater than or equal to a third threshold.

For example, the third threshold may include a value obtained by adding 1 V to the sum of the first pack voltage and the second pack voltage.

If the difference between the first pack voltage of the first battery pack and the second pack voltage of the second battery pack is greater than or equal to the third threshold (Yes in the operation S423), in an operation S425, the vehicle control method according to embodiment may include determining that the risk level is level 2.

If the first current of the first battery pack is not greater than the first reference value during the specified time or more (No in the operation S421), in an operation S427, the vehicle control method according to embodiment may include identifying whether the first current of the first battery pack is greater than the second reference value during the specified time or more.

If the first current of the first battery pack is greater than the second reference value during the specified time or more (Yes in the operation S427), in an operation S429, the vehicle control method according to embodiment may include identifying whether the difference between the first pack voltage of the first battery pack and the second pack voltage of the second battery pack is greater than or equal to a fourth threshold.

For example, the fourth threshold may include a value obtained by adding 1 V to the sum of the first pack voltage and the second pack voltage.

If the difference between the first pack voltage of the first battery pack and the second pack voltage of the second battery pack is not greater than or equal to the third threshold (No in the operation S423), if the first current of the first battery pack is not greater than the second reference value during the specified time or more (No in the operation S427), or if the difference between the first pack voltage of the first battery pack and the second pack voltage of the second battery pack is not greater than or equal to the fourth threshold (No in the operation S429), the vehicle control method according to embodiment may include ending the process.

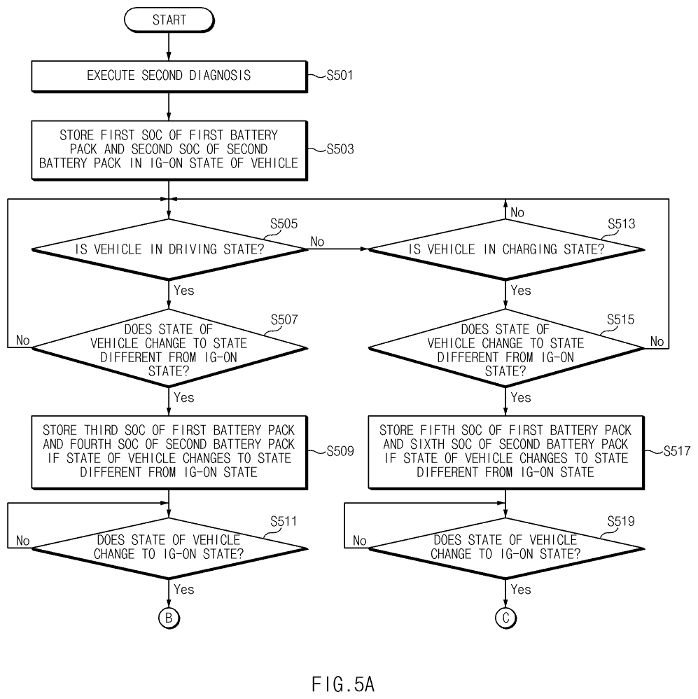

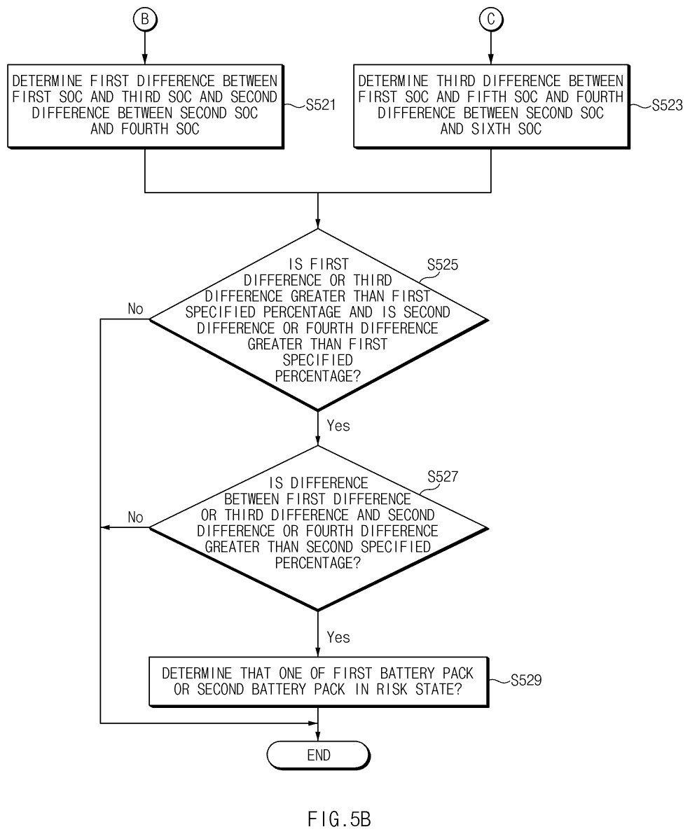

FIGS. 5A and 5B illustrate an example of a flowchart associated with a vehicle control method according to an embodiment of the present disclosure.

Hereinafter, it is assumed that a vehicle control apparatus 100 of FIG. 1 performs processes of FIGS. 5A and 5B. Furthermore, in descriptions of FIGS. 5A and 5B, an operation described as being performed by an apparatus may be understood as being controlled by a processor 110 of the vehicle control apparatus 100.

At least one of the operations of FIGS. 5A and 5B may be performed by the vehicle control apparatus 100 of FIG. 1. At least one of the operations of FIGS. 5A and 5B may be controlled by the processor 110 of FIG. 1. The respective operations of FIGS. 5A and 5B may be sequentially performed, but are not necessarily sequentially performed. For example, an order of the respective operations may be changed, and at least two operations may be performed in parallel.

Referring to FIGS. 5A and 5B, in an operation S501, the vehicle control method according to an embodiment may include executing a second diagnosis. FIGS. 5A and 5B may include details associated with the second diagnosis. For example, the vehicle control method may include performing the operations of FIGS. 5A and 5B, based on the operation S305 of FIG. 3.

In an operation S503, the vehicle control method according to embodiment may include storing a first SOC of a first battery pack and a second SOC of a second battery pack in an Ig-on state of a vehicle.

In an operation S505, the vehicle control method according to an embodiment may include identifying whether the vehicle is in a driving state.

If the vehicle is in the driving state (Yes in the operation S505), in an operation S507, the vehicle control method according to an embodiment may include identifying whether the state of the vehicle changes to a state different from the Ig-on state. The state different from the Ig-on state may include at least one of an Ig-off state or an ACC state, or any combination thereof. However, an embodiment of the present disclosure is not limited to that described above.

If the state of the vehicle changes to the state different from the Ig-on state (Yes in the operation S507), in an operation S509, the vehicle control method according to embodiment may include storing a third SOC of the first battery pack and a fourth SOC of the second battery pack if the state of the vehicle changes to the state different from the Ig-on state.

If the state of the vehicle does not change to the state different from the Ig-on state (No in the operation S507), in the operation S505, the vehicle control method according to embodiment may include identifying whether the vehicle is in the driving state again.

In an operation S511, the vehicle control method according to an embodiment may include identifying whether the state of the vehicle changes to the Ig-on state.

If the vehicle is not in the driving state (Yes in the operation S505), in an operation S513, the vehicle control method according to an embodiment may include identifying whether the vehicle is in a charging state.

If the vehicle is in the charging state (Yes in the operation S513), in an operation S515, the vehicle control method according to an embodiment may include identifying whether the state of the vehicle changes to the state different from the Ig-on state.

If the state of the vehicle changes to the state different from the Ig-on state (Yes in the operation S515), in an operation S517, the vehicle control method according to embodiment may include storing a fifth SOC of the first battery pack and a sixth SOC of the second battery pack if the state of the vehicle changes to the state different from the Ig-on state.

If the state of the vehicle does not change to the state different from the Ig-on state (No in the operation S515), the vehicle control method according to embodiment may include returning to the operation S505 to identify whether the vehicle is in the driving state.

In an operation S519, the vehicle control method according to an embodiment may include identifying whether the state of the vehicle changes to the Ig-on state.

If the state of the vehicle does not change to the Ig-on state (No in the operation S519), the vehicle control method according to embodiment may include identifying whether the state of the vehicle changes to the Ig-on state again.

If the state of the vehicle changes to the Ig-on state (Yes in the operation S511), in an operation S521, the vehicle control method according to embodiment may include determining a first difference between the first Soc and the third SOC and a second difference between the second SOC and the fourth SOC.

If the state of the vehicle changes to the Ig-on state (Yes in the operation S519), in an operation S523, the vehicle control method according to embodiment may include determining a third difference between the first Soc and the fifth SOC and a fourth difference between the second SOC and the sixth SOC.

In an operation S525, the vehicle control method according to embodiment may include identifying whether the first difference or the third difference is greater than a first specified percentage and the second difference or the fourth difference is greater than the first specified percentage.

For example, the first specified percentage may include about 10%.

For example, the vehicle control method may include identifying whether the first difference is greater than the first specified percentage.

For example, the vehicle control method may include identifying whether the third difference is greater than the first specified percentage.

For example, the vehicle control method may include identifying whether the second difference is greater than the first specified percentage.

For example, the vehicle control method may include identifying whether the fourth difference is greater than the first specified percentage.

For example, the vehicle control method may include identifying whether the first difference is greater than the first specified percentage and the second difference is greater than the first specified percentage.

For example, the vehicle control method may include identifying whether the second difference is greater than the first specified percentage and the fourth difference is greater than the first specified percentage.

If the first difference or the third difference is greater than the first specified percentage and the second difference or the fourth difference is greater than the first specified percentage (Yes in the operation S525), in an operation S527, the vehicle control method according to embodiment may include identifying whether a difference between the first difference or the third difference and the second difference or the fourth difference is greater than a second specified percentage.

For example, the second specified percentage may include about 2%.

For example, the vehicle control method may include identifying whether the difference between the first difference and the second difference is greater than the second specified percentage.

For example, the vehicle control method may include identifying whether the difference between the third difference and the fourth difference is greater than the second specified percentage.

If the difference between the first difference or the third difference and the second difference or the fourth difference is greater than the second specified percentage (Yes in the operation S527), in an operation S529, the vehicle control method according to embodiment may include determining that one of the first battery pack or the second battery pack is in a risk state.

For example, the vehicle control method may include determining whether a battery pack in which a difference between an SOC at a first time point and an SOC at a second time point is relatively large is in the risk state.

If the first difference or the third difference is not greater than the first specified percentage and the second difference or the fourth difference is not greater than the first specified percentage (No in the operation S525) or if the difference between the first difference or the third difference and the second difference or the fourth difference is not greater than the second specified percentage (No in the operation S527), the vehicle control method according to embodiment may end the process.

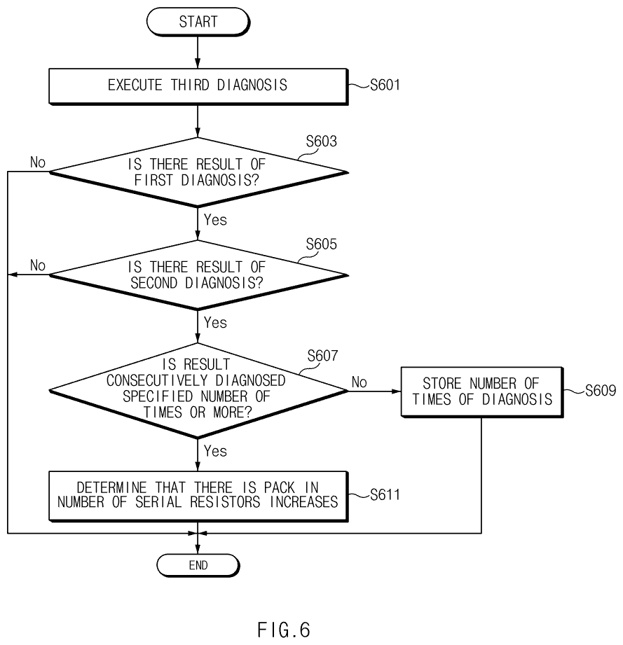

FIG. 6 illustrates an example of a flowchart associated with a vehicle control method according to an embodiment of the present disclosure.

Hereinafter, it is assumed that a vehicle control apparatus 100 of FIG. 1 performs a process of FIG. 6. Furthermore, in a description of FIG. 6, an operation described as being performed by an apparatus may be understood as being controlled by a processor 110 of the vehicle control apparatus 100.

At least one of the operations of FIG. 6 may be performed by the vehicle control apparatus 100 of FIG. 1. At least one of the operations of FIG. 6 may be controlled by the processor 110 of FIG. 1. The respective operations of FIG. 6 may be sequentially performed, but are not necessarily sequentially performed. For example, an order of the respective operations may be changed, and at least two operations may be performed in parallel.

Referring to FIG. 6, in an operation S601, the vehicle control method according to an embodiment may include executing a third diagnosis.

In an operation S603, the vehicle control method according to an embodiment may include identifying whether there is a result of a first diagnosis.

If there is the result of the first diagnosis (Yes in the operation S603), in an operation S605, the vehicle control method according to an embodiment may include identifying whether there is a result of a second diagnosis.

If there is the result of the second diagnosis (Yes in the operation S605), in an operation S607, the vehicle control method according to an embodiment may include identifying whether the result is consecutively diagnosed a specified number of times or more.

If the result is not consecutively diagnosed the specified number of times or more (No in the operation S607), in an operation S609, the vehicle control method according to an embodiment may include storing the number of times of diagnosis.

If the result is consecutively diagnosed the specified number of times or more (Yes in the operation S607), in an operation S611, the vehicle control method according to an embodiment may include determining that there is a pack in which the number of serial resistors increases.

If there is no result of the first diagnosis (No in the operation S603) or if there is no result of the second diagnosis (No in the operation S605), the vehicle control method according to embodiment may include ending the process.

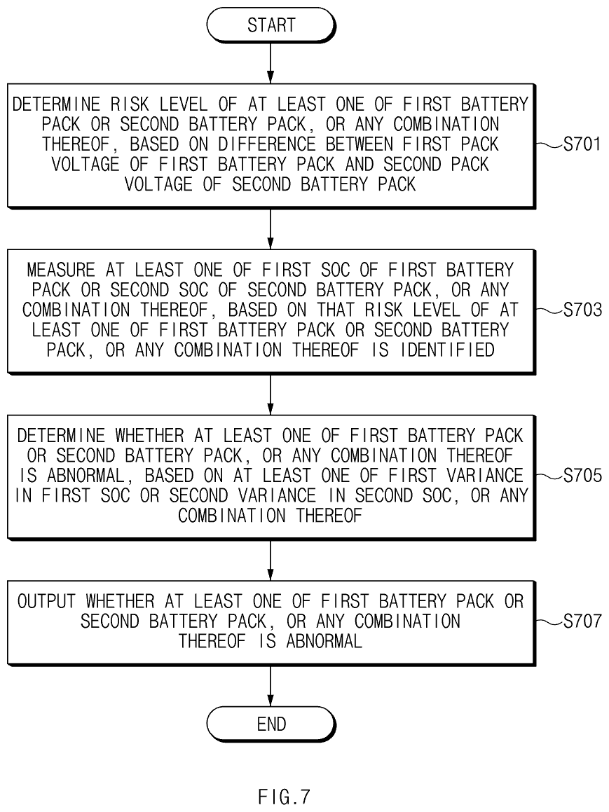

FIG. 7 illustrates an example of a flowchart associated with a vehicle control method according to an embodiment of the present disclosure.

Hereinafter, it is assumed that a vehicle control apparatus 100 of FIG. 1 performs a process of FIG. 7. Furthermore, in a description of FIG. 7, an operation described as being performed by an apparatus may be understood as being controlled by a processor 110 of the vehicle control apparatus 100.

At least one of the operations of FIG. 7 may be performed by the vehicle control apparatus 100 of FIG. 1. At least one of the operations of FIG. 7 may be controlled by the processor 110 of FIG. 1. The respective operations of FIG. 7 may be sequentially performed, but are not necessarily sequentially performed. For example, an order of the respective operations may be changed, and at least two operations may be performed in parallel.

Referring to FIG. 7, in an operation $701, the vehicle control method according to embodiment may include determining a risk level of at least one of a first battery pack or a second battery pack, or any combination thereof, based on a difference between a first pack voltage of the first battery pack and a second pack voltage of the second battery pack.

For example, the vehicle control method may include identifying the first pack voltage and the second pack voltage, based on identifying a first internal current of the first battery pack and a second internal current of the second battery pack.

For example, the vehicle control method may include identifying the risk level of the first battery pack, based on that the sum of voltages of a plurality of first battery cells included in the first battery pack and the first pack voltage are different from each other.

For example, the vehicle control method may include identifying the risk level of the second battery pack, based on that the sum of voltages of a plurality of second battery cells included in the second battery pack and the second pack voltage are different from each other.

For example, the vehicle control method may include obtaining the first pack voltage, based on a voltage of the first battery pack, which is measured during a specified time.

For example, the vehicle control method may include obtaining the second pack voltage, based on a voltage of the second battery pack, which is measured during the specified time.

In an operation S703, the vehicle control method according to embodiment may include measuring at least one of a first SOC of the first battery pack or a second SOC of the second battery pack, or any combination thereof, based on that the risk level of the at least one of the first battery pack or the second battery pack, or the any combination thereof is identified.

For example, the vehicle control method may include measuring the at least one of the first Soc or the second SOC, or the any combination thereof, based on that a state of a vehicle including the first battery pack and the second battery pack changes from an Ig-on state to a state different from the Ig-on state.

For example, the vehicle control method may include determining that the risk level of the at least one of the first battery pack or the second battery, or the any combination thereof is a first level, based on that the difference between the first pack voltage and the second pack voltage is greater than or equal to a first threshold and is less than a second threshold.

For example, the vehicle control method may include determining that the risk level of the at least one of the first battery pack or the second battery pack or the any combination thereof is a second level indicating greater risk than the first level, based on that the difference between the first pack voltage and the second pack voltage is greater than or equal to the second threshold.

For example, the vehicle control method may include identifying at least one of a first internal current of the first battery pack or a second internal current of the second battery pack, or any combination thereof.

For example, the vehicle control method may include determining whether the at least one of the first internal current or the second internal current, or the any combination thereof is in a first interval which is less than or equal to a first reference value, in a second interval which is greater than the first reference value and is less than or equal to a second reference value, or in a third interval which is greater than the second reference value.

For example, the vehicle control method may include determining the risk level of the at least one of the first battery pack or the second battery pack, or the any combination thereof, depending on the interval in which there is the at least one of the first internal current or the second internal current, or the any combination thereof.

In an operation S705, the vehicle control method according to embodiment may include determining whether the at least one of the first battery pack or the second battery pack, or the any combination thereof is abnormal, based on at least one of a first variance in the first SOC or a second variance in the second SOC, or any combination thereof.

For example, the vehicle control method may include measuring the at least one of the first variance or the second variance, or the any combination thereof, based on that the state of the vehicle changes from an Ig-on state to a state different from the Ig-on state.

For example, the vehicle control method may include determining an abnormal state of the first battery pack, if the first variance between the first variance and the second variance is greater than the second variance.

For example, the vehicle control method may include determining an abnormal state of the second battery pack, if the second variance between the first variance and the second variance is greater than the first variance.

For example, the vehicle control method may include a first number of times that the risk level of the at least one of the first battery pack or the second battery pack, or the any combination thereof is determined. For example, the vehicle control method may include identifying whether the risk level of the at least one of the first battery pack or the second battery pack, or the any combination thereof is determined a specified number of times or more.

For example, the vehicle control method may include identifying a second number of times that the abnormal state of the at least one of the first battery pack or the second battery pack, or the any combination thereof is determined. For example, the vehicle control method may include identifying whether the abnormal state of the at least one of the first battery pack or the second battery pack, or the any combination thereof is determined the specified number of times or more.

For example, the vehicle control method may include determining that there is an element causing an increase in resistance value in the inside of the at least one of the first battery pack or the second battery pack, or the any combination thereof, based on that the number of times that the risk level of the at least one of the first battery pack or the second battery pack, or the any combination thereof is determined and the number of times that the abnormal state of the at least one of the first battery pack or the second battery pack, or the any combination thereof is determined are greater than or equal to the specified number of times.

For example, the vehicle control method may include storing at least one of the first number of times or the second number of times, or the any combination thereof, based on that at least one of the first number of times or the second number of times is less than the specified number of times. For example, the specified number of times may include about 3 times.

In an operation S707, the vehicle control method according to embodiment may include outputting whether the at least one of the first battery pack or the second battery pack, or the any combination thereof is abnormal.

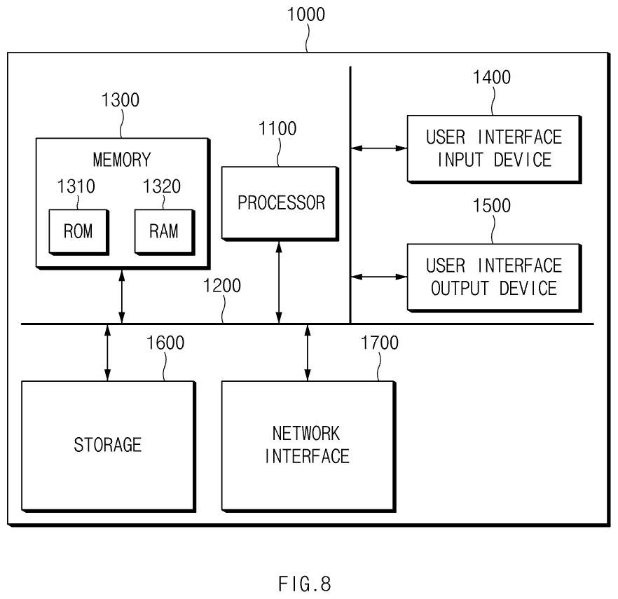

FIG. 8 illustrates a computing system associated with a vehicle control apparatus or a vehicle control method according to an embodiment of the present disclosure.

Referring to FIG. 8, a computing system 1000 may include at least one processor 1100, a memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with embodiments disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, and a CD-ROM.

The storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The present technology may overcome a limitation due to low voltage sensing resolution in a commercial EV which uses a plurality of battery system assemblies (BSAs).

Furthermore, the present technology may determine whether there is an external resistor of a cell electrode using a plurality of voltage and current sensors loaded into the plurality of BSAs.

Furthermore, the present technology may detect whether abnormality occurs in a battery pack and may prevent fire.

In addition, various effects ascertained directly or indirectly through the present disclosure may be provided.

Hereinabove, although the present disclosure has been described with reference to embodiments and the accompanying drawings, the present disclosure is not limited thereto, but may be variously modified and altered by those having ordinary skill in the art to which the present disclosure pertains without departing from the spirit and scope of the present disclosure claimed in the following claims.

Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A vehicle control apparatus, comprising:
a first battery pack;
a second battery pack; and
a processor,
wherein the processor is configured to:
determine a risk level of at least one of the first battery pack, the second battery pack, or any combination thereof, based on a difference between a first pack voltage of the first battery pack and a second pack voltage of the second battery pack;
measure at least one of a first state of charge (SOC) of the first battery pack, a second SOC of the second battery pack, or any combination thereof, based on that the risk level of the at least one of the first battery pack, the second battery pack, or the any combination thereof is determined; and
determine whether the at least one of the first battery pack, the second battery pack, or the any combination thereof is abnormal, based on at least one of a first variance in the first Soc, a second variance in the second SOC, or any combination thereof.

2. The vehicle control apparatus of claim 1, wherein the processor is configured to:
identify the first pack voltage and the second pack voltage, based on identifying a first internal current of the first battery pack and a second internal current of the second battery pack.

3. The vehicle control apparatus of claim 1, wherein the first battery pack includes a plurality of first battery cells,
wherein the second battery pack includes a plurality of second battery cells, and
wherein the processor is configured to:
determine the risk level of the first battery pack, based on that the sum of voltages of the plurality of first battery cells and the first pack voltage are different from each other; or
determine the risk level of the second battery pack, based on that the sum of voltages of the plurality of second battery cells and the second pack voltage are different from each other.

4. The vehicle control apparatus of claim 1, wherein the processor is configured to:
measure the at least one of the first soc, the second SOC, or the any combination thereof, based on that a state of a vehicle including the first battery pack and the second battery pack changes from an ignition (Ig)-on state to a state different from the Ig-on state; and
measure the at least one of the first variance, the second variance, or the any combination thereof, based on that the state of the vehicle changes from a state different from the Ig-on state to the Ig-on state.

5. The vehicle control apparatus of claim 1, wherein the processor is configured to:
determine an abnormal state of the first battery pack when the first variance is greater than the second variance; or
determine an abnormal state of the second battery pack when the second variance is greater than the first variance.

6. The vehicle control apparatus of claim 1, wherein the processor is configured to:
obtain the first pack voltage, based on a voltage of the first battery pack measured during a specified time; or
obtain the second pack voltage, based on a voltage of the second battery pack measured during the specified time.

7. The vehicle control apparatus of claim 1, wherein the processor is configured to:
determine that the risk level of the at least one of the first battery pack, the second battery pack, or the any combination thereof is a first level, based on that a difference between the first pack voltage and the second pack voltage is greater than or equal to a first threshold and is less than a second threshold.

8. The vehicle control apparatus of claim 7, wherein the processor is configured to:
determine that the risk level of the at least one of the first battery pack, the second battery pack, or the any combination thereof is a second level indicating greater risk than the first level, based on that the difference between the first pack voltage and the second pack voltage is greater than or equal to the second threshold.

9. The vehicle control apparatus of claim 1, wherein the processor is configured to:
identify at least one of a first internal current of the first battery pack, a second internal current of the second battery pack, or any combination thereof;
determine whether the at least one of the first internal current, the second internal current, or the any combination thereof is in a first interval less than or equal to a first reference value, in a second interval greater than the first reference value and less than or equal to a second reference value, or in a third interval greater than the second reference value; and
determine the risk level of the at least one of the first battery pack, the second battery pack, or the any combination thereof, based on an interval in which there is the at least one of the first internal current, the second internal current, or the any combination thereof.

10. The vehicle control apparatus of claim 1, wherein the processor is configured to:
identify a first number of times that the risk level of the at least one of the first battery pack, the second battery pack, or the any combination thereof is determined;
identify a second number of times that an abnormal state of the at least one of the first battery pack, the second battery pack, or the any combination thereof is determined; and
determine that there is an element causing an increase in a resistance value in an inside of the at least one of the first battery pack, the second battery pack, or the any combination thereof, based on that the first number of times is greater than or equal to a specified number of times and the second number of times is greater than or equal to the specified number of times.

11. The vehicle control apparatus of claim 1, wherein the processor is configured to:
identify a first number of times that the risk level of the at least one of the first battery pack, the second battery pack, or the any combination thereof is determined;
identify a second number of times that an abnormal state of the at least one of the first battery pack, the second battery pack, or the any combination thereof is determined; and
store at least one of the first number of times, the second number of times, or any combination thereof, based on that at least one of the first number of times, the second number of times, or any combination thereof is less than a specified number of times.

12. The vehicle control apparatus of claim 1, wherein the processor is configured to:
output whether the at least one of the first battery pack, the second battery pack, or the any combination thereof is abnormal.

13. A vehicle control method, comprising:
determining, by a processor, a risk level of at least one of a first battery pack, a second battery pack, or any combination thereof, based on a difference between a first pack voltage of the first battery pack and a second pack voltage of the second battery pack;
measuring, by the processor, at least one of a first state of charge (SOC) of the first battery pack, a second SOC of the second battery pack, or any combination thereof, based on that the risk level of the at least one of the first battery pack, the second battery pack, or the any combination thereof is determined; and
determining, by the processor, whether the at least one of the first battery pack, the second battery pack, or the any combination thereof is abnormal, based on at least one of a first variance in the first Soc, a second variance in the second SOC, or any combination thereof.

14. The vehicle control method of claim 13, further comprising:
identifying the first pack voltage and the second pack voltage, based on identifying a first internal current of the first battery pack and a second internal current of the second battery pack.

15. The vehicle control method of claim 13, wherein the first battery pack includes a plurality of first battery cells, and
wherein the second battery pack includes a plurality of second battery cells,
further comprising:
determining the risk level of the first battery pack, based on that the sum of voltages of the plurality of first battery cells and the first pack voltage are different from each other; or
determining the risk level of the second battery pack, based on that the sum of voltages of the plurality of second battery cells and the second pack voltage are different from each other.

16. The vehicle control method of claim 13, further comprising:
measuring the at least one of the first soc, the second SOC, or the any combination thereof, based on that a state of a vehicle including the first battery pack and the second battery pack changes from an ignition (Ig)-on state to a state different from the Ig-on state; and
measuring the at least one of the first variance, the second variance, or the any combination thereof, based on that the state of the vehicle changes from a state different from the Ig-on state to the Ig-on state.

17. The vehicle control method of claim 13, further comprising:
determining an abnormal state of the first battery pack when the first variance is greater than the second variance; or
determining an abnormal state of the second battery pack when the second variance is greater than the first variance.

18. The vehicle control method of claim 13, further comprising:
obtaining the first pack voltage, based on a voltage of the first battery pack measured during a specified time; or
obtaining the second pack voltage, based on a voltage of the second battery pack measured during the specified time.

19. The vehicle control method of claim 13, further comprising:
determining that the risk level of the at least one of the first battery pack, the second battery pack, or the any combination thereof is a first level, based on that a difference between the first pack voltage and the second pack voltage is greater than or equal to a first threshold and is less than a second threshold; or
determining that the risk level of the at least one of the first battery pack, the second battery pack, or the any combination thereof is a second level indicating greater risk than the first level, based on that the difference between the first pack voltage and the second pack voltage is greater than or equal to the second threshold.

20. The vehicle control method of claim 13, further comprising:
identifying at least one of a first internal current of the first battery pack, a second internal current of the second battery pack, or any combination thereof;
determining whether the at least one of the first internal current, the second internal current, or the any combination thereof is in a first interval less than or equal to a first reference value, in a second interval greater than the first reference value and less than or equal to a second reference value, or in a third interval greater than the second reference value; and
determining the risk level of the at least one of the first battery pack, the second battery pack, or the any combination thereof, based on an interval in which there is the at least one of the first internal current, the second internal current, or the any combination thereof.
